(19) United States
(12) Patent Application Publication
(10) Pub. No.: US 2009/0311868 A1
(43) Pub. Date: Dec. 17, 2009

(54) Semiconductor device manufacturing method

(75) Inventors: Masafumi Hayashi, Kumamoto (JP); Eiji Uramoto, Kumamoto (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/457,496

(22) Filed: Jun. 12, 2009

(30) Foreign Application Priority Data
Jun. 16, 2008 (JP) 156619/2008

(51) Int. Cl. H01L 21/306

(52) U.S. Cl. 438/706; 257/E21.215

(57) ABSTRACT

In a semiconductor device manufacturing method according to this invention, an SiO₂ film used as a mask at the time of trench formation is removed by a wet process after hydrophilic treatment is performed on the interior of a hydrophobic trench.

The present application is based on a Japanese patent application, Japanese Patent Application No. 2008-156619.

### BACKGROUND OF THE INVENTION

The present invention relates to a semiconductor device manufacturing method.

The process of forming a mask by forming a film containing silicon on a semiconductor substrate and then forming a trench by etching has been performed to form a silicon trench formation for element isolation. Some Patent Documents disclose such a technology.

National Publication of International Patent Application No. 2003-511857 discloses a method of forming an STI (Shallow Trench Isolation) structure. A trench is formed by etching with an SiO/SiN/SiO₂ mask. Then the trench is filled with an oxide after removing the SiON (SiO) on the SiN, CMP (Chemical Mechanical Polishing) is performed using the SiN as an etching stopper.

Japanese Patent Laid-Open No. 2005-129946 discloses solutions of SPM, APM, HPM, or the like for cleaning after trench dry etching of STI.

Japanese Patent Laid-Open No. 2003-309108 discloses solution of FPM, APM, SPM, or the like for cleaning after trench dry etching.

However, the inventors of the present application have found that the following problem occurred when a trench surrounding a predetermined region was formed in a silicon substrate. A trench is formed by forming a mask on a silicon substrate and then etching the silicon substrate using the mask. After a residue of the etching is cleaning with cleaning solution, the mask is removed with removing solution. A residue of the mask is left in the region surrounded by the trench after removing the mask. The inventors earnestly investigated the reason of the mask residue and found that an air bubble was formed in the region surrounded by the trench because the surface of the trench became hydrophobic after cleaning the residue of the etching and the removing solution was repelled by the trench. The repelled removing solution holds air in a region surrounded by the trench, and an air bubble is formed in the region. Thus the air bubble disturbs the removal of the mask.

A mask residue is formed above reason and it is explained more precisely with reference to FIGS. 7A to 7D to 10A and 10B.

FIGS. 7A to 7D are sectional views schematically showing a semiconductor device manufacturing process according to the present invention. FIGS. 8A and 8B are a sectional view taken along line X-X′ and a plan view schematically showing the semiconductor device manufacturing process according to the present invention. FIGS. 9A and 9B are a sectional view taken along line XI-XI′ and a plan view for explaining a problem with the semiconductor device according to the present invention. FIGS. 10A and 10B are a sectional view taken along line XII-XII′ and a plan view for explaining the problem with the semiconductor device according to the present invention.

An example will be described where a silicon trench is formed in a semiconductor substrate, and an SiO₂ residue (a residue shown in FIGS. 10A and 10B, i.e., an SiO₂ film 104a) is formed in a region surrounded by the trench (a region α shown in FIG. 8B) at the time of removing SiO₂ on SiN as a trench etching mask.

First, an SiO₂ film 102 is formed on a semiconductor silicon substrate 101, and an SiN film 103 and an SiO₂ film 104 are stacked on the SiO₂ film 102 in order, as shown in FIGS. 7A and 7B. The SiO₂ film 104 serves as an etching mask at the time of silicon trench formation. A photo resist 105 formed on the SiO₂ film 104 is patterned by photolithography, an opening is formed in the SiO₂ film 104, the SiN film 103, and the SiO₂ film 102 by dry etching using the photo resist 105 as a mask (FIG. 7C), and the photo resist 105 is stripped (FIG. 7D). With these operations, a trench etching mask is formed on the semiconductor silicon substrate 101.

A trench 106 is formed in the semiconductor silicon substrate 101 by dry etching using the trench etching mask (FIGS. 8A and 8B). Hydrofluoric acid treatment is performed to remove a generated etching deposit (FIGS. 9A and 9B). After that, the SiO₂ film 104 is removed by a wet process (FIGS. 10A and 10B).

At this time, silicon on the surface of the trench 106 is hydrophobized by the hydrofluoric acid treatment. In the hydrophobic trench 106, at the time of trench etching mask removal by the subsequent wet process, a chemical solution used for the wet process is repelled at an inner wall surface of the trench 106, and an air bubble 108 is likely to be formed in the region α surrounded by the trench 106 (FIGS. 9A and 9B). The air bubble 108 prevents the subsequent removal of the SiO₂ film 104 and forms a residue, i.e., the SiO₂ film 104a (FIGS. 10A and 10B).

### SUMMARY

A semiconductor device manufacturing method according to the present invention comprises a step of forming a mask layer containing silicon on a semiconductor substrate, a step of forming a photo resist on the mask layer, a step of forming a pattern surrounding a predetermined region in the photo resist, a step of etching the mask layer containing silicon using the pattern and forming a mask, a step of forming a trench in the semiconductor substrate using the mask, a step of cleaning an interior of the trench with a cleaning solution containing hydrofluoric acid, a step of performing hydrophilic treatment on the interior of the trench, and a step of removing the mask by a wet process after the hydrophilic treatment step.

In the semiconductor device manufacturing method, after the trench is cleaned, and the hydrophilic treatment is performed on the interior of the trench, the mask used for the trench formation is removed by the wet process. According to the semiconductor device manufacturing method, generation of a mask residue can be suppressed.

More specifically, when the mask, in which the trench is formed, is to be removed by the wet process, if the interior of the trench is hydrophobic, a chemical solution used for the wet process is repelled by the trench, the chemical solution repelled into a region surrounded by the trench holds air, and an air bubble is likely to be formed. The air bubble prevents removal of a part of the mask which is covered with the air bubble and causes generation of a mask residue. For this reason, according to the semiconductor device manufacturing method of the present invention, the hydrophilic treatment is performed on the interior of the trench after the cleaning of the trench. Accordingly, the chemical solution used for the wet process is not repelled, and formation of an air bubble at the time of the mask removal is suppressed. This makes it possible to suppress generation of a mask residue. The occurrence of defects due to such a residue is reduced, and the yields and reliability of semiconductor devices can be improved.

### BRIEF DESCRIPTION OF THE DRAWINGS

The above and other objects, advantages and features of the present invention will be more apparent from the following description taken in conjunction with the accompanying drawings, in which:

FIGS. 1A to 1D are sectional views schematically showing a semiconductor device manufacturing process according to the present invention;

FIGS. 2A and 2B are a sectional view taken along line I-I′ and a plan view schematically showing the semiconductor device manufacturing process according to the present invention;

FIGS. 3A and 3B are a sectional view taken along line II-II′ and a plan view schematically showing the semiconductor device manufacturing process according to the present invention;

FIGS. 4A and 4B are a sectional view taken along line III-III′ and a plan view schematically showing the semiconductor device manufacturing process according to the present invention;

FIGS. 5A and 5B are a sectional view taken along line IV-IV′ and a plan view schematically showing the semiconductor device manufacturing process according to the present invention;

FIGS. 6A and 6B are sectional views schematically showing the semiconductor device manufacturing process according to the present invention;

FIGS. 7A to 7D are sectional views schematically showing a semiconductor device manufacturing process for explaining a problem with the present invention;

FIGS. 8A and 8B are a sectional view taken along line X-X′ and a plan view schematically showing the semiconductor device manufacturing process for explaining the problem with the present invention;

FIGS. 9A and 9B are a sectional view taken along line XI-XI′ and a plan view for explaining the problem with a semiconductor device; and

FIGS. 10A and 10B are a sectional view taken along line XII-XII′ and a plan view for explaining the problem with a semiconductor device.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

A preferred embodiment of a semiconductor device manufacturing method according to the present invention will be described below with reference to the drawings. Note that, in a description of the drawings, the same components are denoted by the same reference numerals, and a repetitive description will be omitted.

### First Embodiment

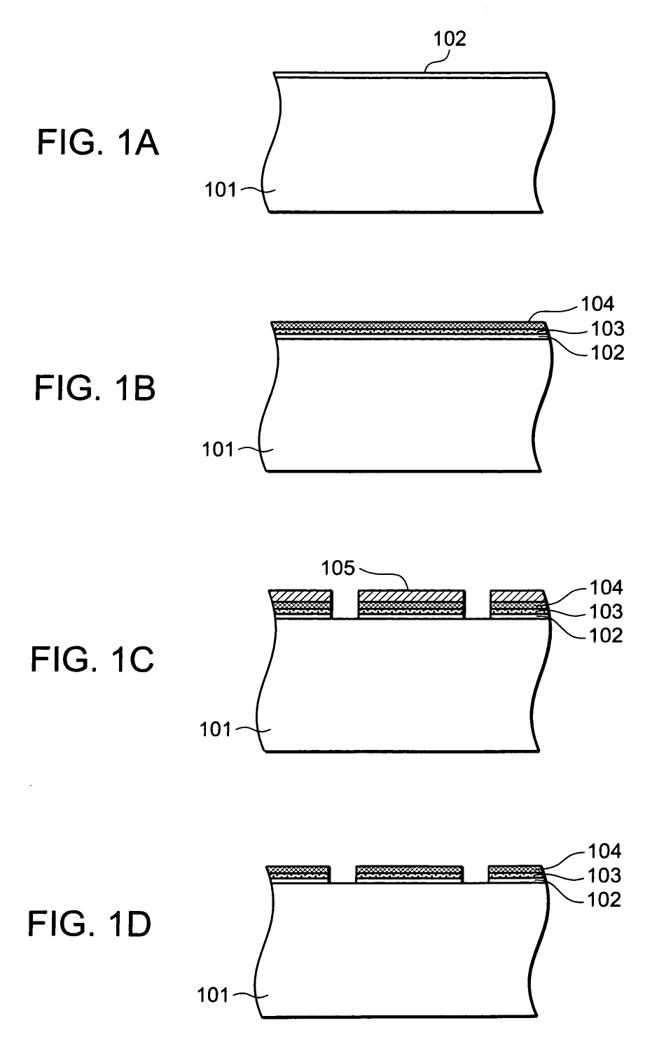

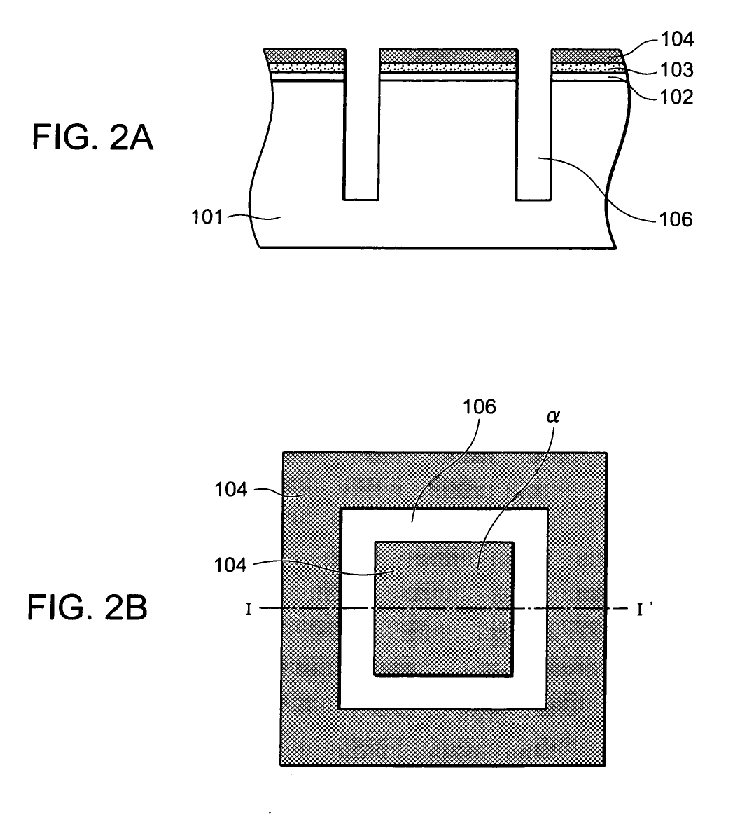

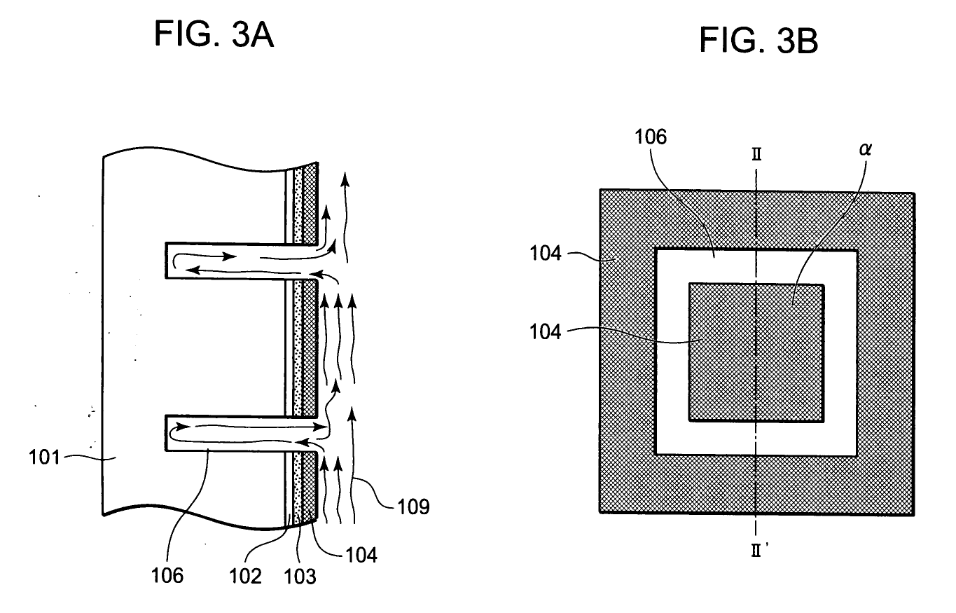

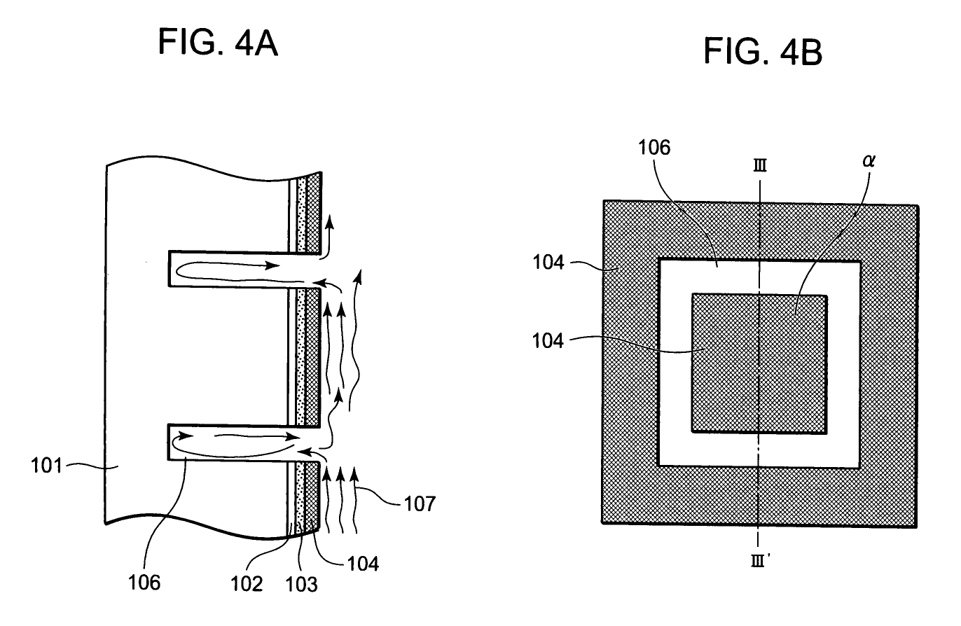

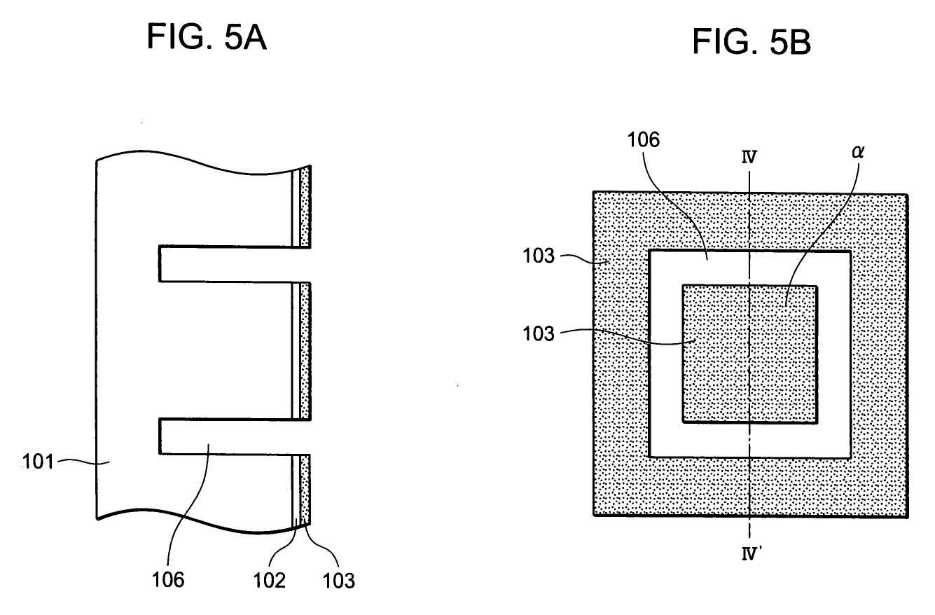

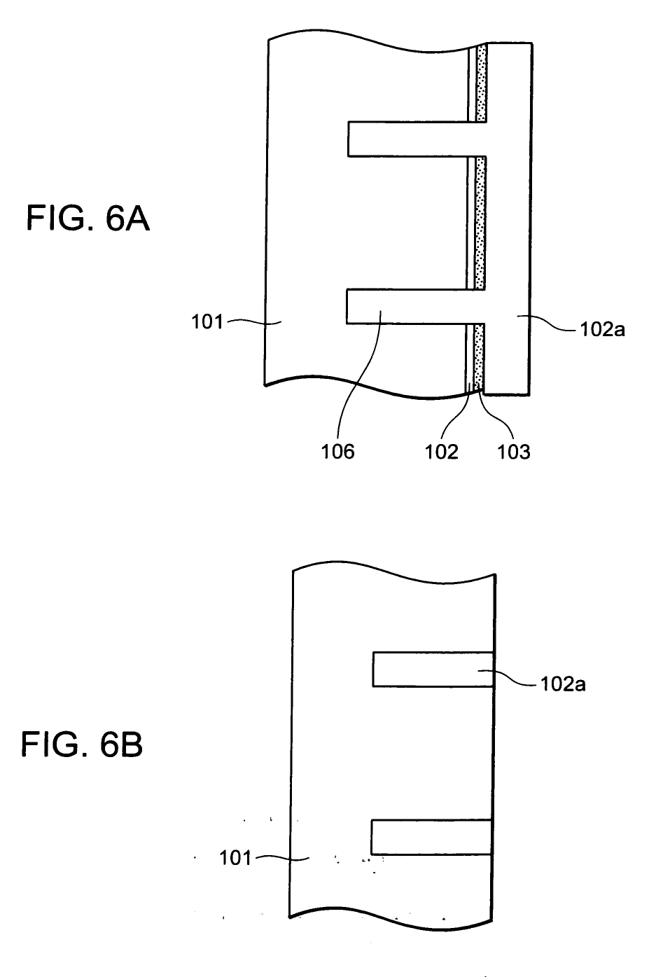

FIGS. 1A to 1D are sectional views schematically showing a semiconductor device manufacturing process according to the present invention. FIGS. 2A and 2B are a sectional view taken along line I-I′ and a plan view schematically showing the semiconductor device manufacturing process according to the present invention. FIGS. 3A and 3B are a sectional view taken along line II-II′ and a plan view schematically showing the semiconductor device manufacturing process according to the present invention. FIGS. 4A and 4B are a sectional view taken along line III-III′ and a plan view schematically showing the semiconductor device manufacturing process according to the present invention. FIGS. 5A and 5B are a sectional view taken along line IV-IV′ and a plan view schematically showing the semiconductor device manufacturing process according to the present invention. FIGS. 6A and 6B are sectional views schematically showing the semiconductor device manufacturing process according to the present invention.

A semiconductor device manufacturing method will be described below with reference to FIGS. 1A to 1D to 6A and 6B. In this embodiment, a silicon trench 106 is formed to surround a predetermined region α on a semiconductor silicon substrate 101 in plan view (see FIG. 2B).

As shown in FIGS. 1A and 1B, an SiO₂ film 102 is first formed on the semiconductor silicon substrate 101, and an SiN film 103 and an SiO₂ film 104 are stacked on the SiO₂ film 102 in order, thereby forming a mask layer. The SiO₂ film 104 serves as an etching mask at the time of silicon trench formation. A photo resist 105 formed on the SiO₂ film 104 is patterned by photolithography, an opening is formed in the SiO₂ film 104, the SiN film 103, and the SiO₂ film 102 by dry etching using the photo resist 105 as a mask (FIG. 1C), and then the photo resist 105 is stripped (FIG. 1D). With these operations, a trench etching mask is formed on the semiconductor silicon substrate 101.

The trench 106 is formed in the semiconductor silicon substrate 101 by dry etching using the trench etching mask (FIGS. 2A and 2B). The dry etching is performed using, e.g., a chlorinated gas. After that, the trench 106 is cleaned with a cleaning solution containing hydrofluoric acid such as FPM (hydrofluoric acid-hydrogen peroxide mixture) or dilute hydrofluoric acid in order to remove a generated etching deposit. The hydrofluoric acid used for the cleaning hydrophobizes the interior of the trench 106. That is, silicon at an inner wall surface of the trench 106 is hydrophobized.

Hydrophilic treatment is performed on the interior of the trench 106 using a hydrophilizing solution 109 (FIGS. 3A and 3B). As shown in FIG. 3A, the hydrophilizing solution 109 hydrophilizes the surface of the semiconductor silicon substrate 101 and the interior of the trench 106. An aqueous cleaning solution is preferably used for the hydrophilic treatment. A chemical solution containing, e.g., an ammonia-hydrogen peroxide mixture (APM) and a sulfuric acid-hydrogen peroxide mixture (SPM) is preferable as the hydrophilizing solution 109. The mixtures facilitate the hydrophilic treatment of the trench 106. The hydrophilic treatment may be performed by UV-cure treatment, ashing, oxidation, or the like.

The SiO₂ film 104 is removed by a wet process (FIGS. 4A and 4B). As shown in FIG. 4A, a wet process solution 107 penetrates into the surface of the semiconductor silicon substrate 101 and the interior of the trench 106. The wet process solution 107 removes the SiO₂ film 104 (FIGS. 5A and 5B). An acidic chemical solution such as hydrofluoric acid can be used as the wet process solution 107. Examples of the wet process solution 107 include a hydrofluoric acid-ammonium fluoride mixture or a high concentration hydrofluoric acid which has enough etch rate to silicon oxide film and more preferably include a hydrofluoric acid-ammonium fluoride mixture. The wet process is performed subsequent to the above-described hydrophilic treatment. This makes it possible to remove the SiO₂ film 104 while the interior of the trench 106 is in a hydrophobized state.

After that, as shown in FIG. 6A, the trench 106 is filled with the SiO₂ film 102a, planarization is performed, and the SiN film 103 is removed (FIG. 6B).

As shown in FIG. 2B, the trench 106 surrounds the predetermined region α on the semiconductor silicon substrate 101 in plan view. In this case, formation of an air bubble 108 in the region α surrounded by the trench 106 is considered to be caused by the following: since the trench 106 is formed around the region α, the wet process solution 107 is repelled from all directions toward the inside of the region α, and air is likely to be collected in the region α.

A size for the region α which is likely to cause formation of the air bubble 108 is not less than 5 μm² and is not more than 100 μm². If the region α is on a level lower than its surroundings (e.g., if a diffusion layer is formed in the region α), a size of 50 μm² or less is likely to cause formation of an air bubble. If the center of the diffusion layer and that of the region α almost coincide with each other in plan view, an air bubble is more likely to be formed. If the size of the region α is not more than 30 μm² when the region α is almost on the same level as its surroundings, an air bubble can be generated.

For example, an STI pattern may be formed in the region α surrounded by the trench 106. With this arrangement, air bubbles become more likely to gather. The region α is capable of ensuring that an adjacent element can withstand a high voltage at the time of application of the voltage to the device and cutting off noise caused by a high voltage, a high current, or high-speed operation.

Advantages of this embodiment will be described.

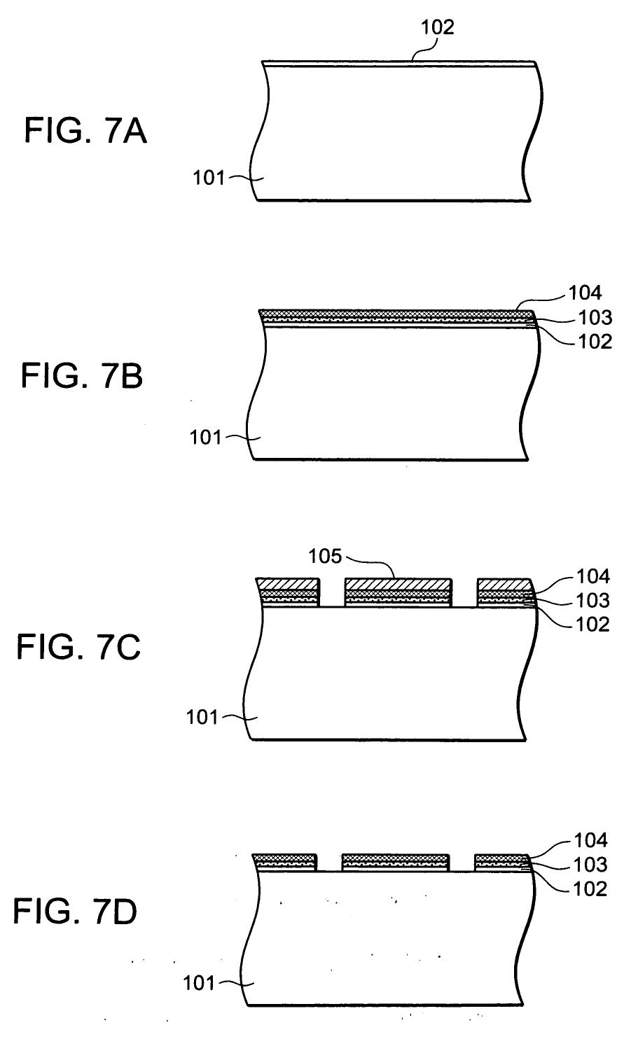

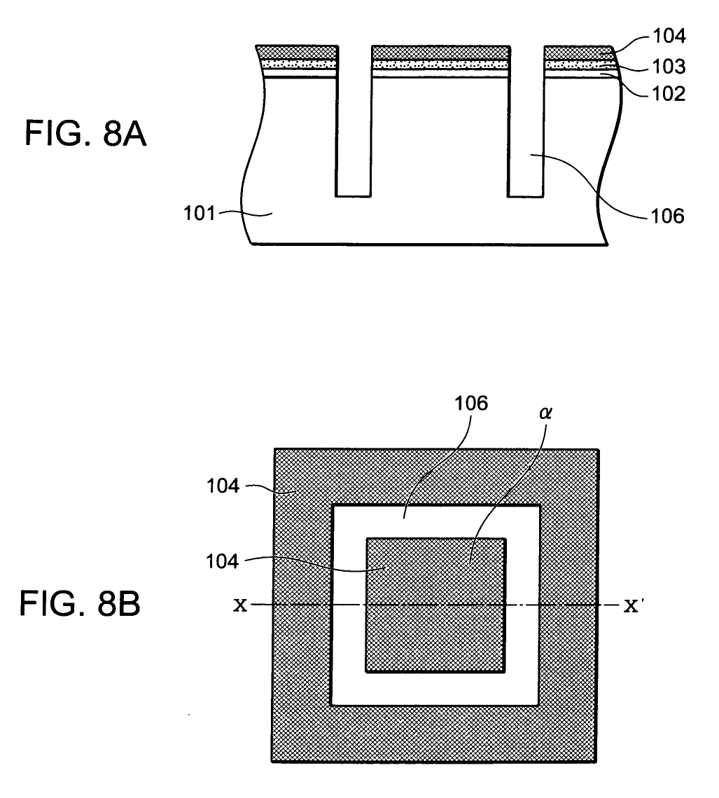

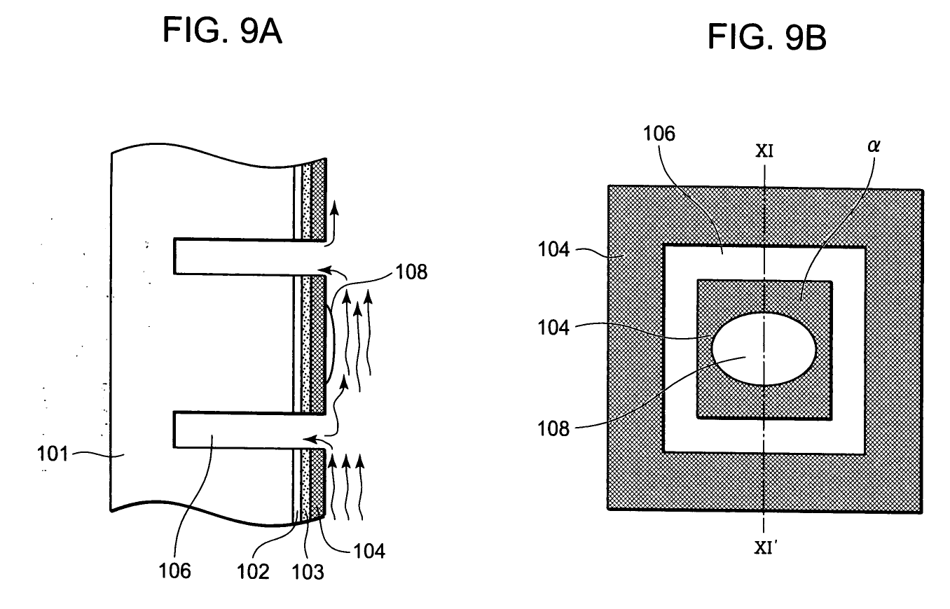

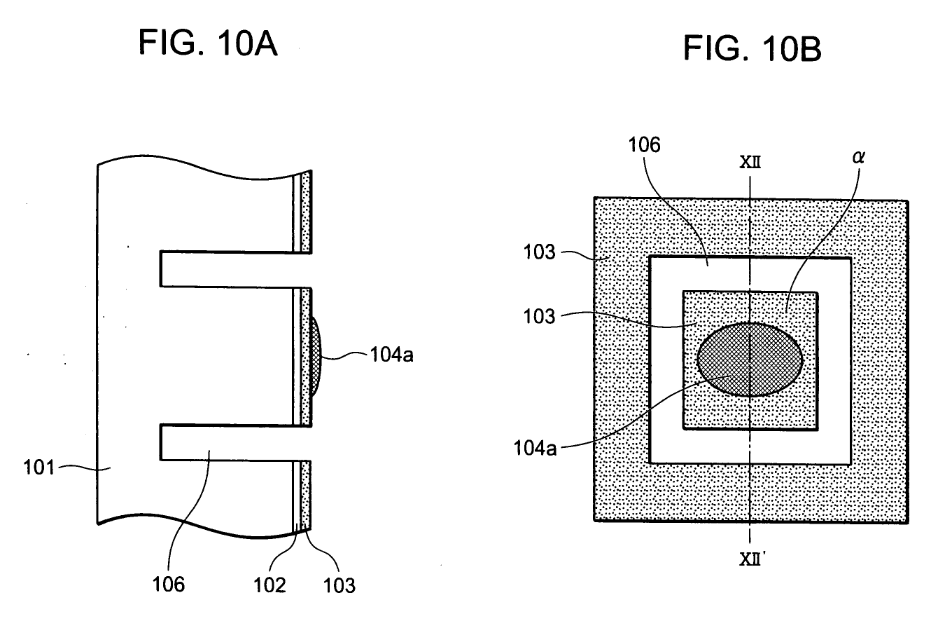

In the semiconductor device manufacturing method shown in FIGS. 7A to 7D to 10A and 10B, the silicon on the surface of the trench 106 is hydrophobized by the hydrofluoric acid treatment. If the trench 106 is hydrophobic, as described above, the chemical solution used to remove the trench formation mask is repelled by the trench 106, the repelled chemical solution holds air in the region α surrounded by the trench 106, and the air bubble 108 is likely to be formed.

In contrast with this, in the semiconductor device manufacturing method according to this embodiment, the SiO₂ film 104 used as the mask at the time of formation of the trench 106 is removed by the wet process after the hydrophilic treatment is performed on the interior of the hydrophobic trench 106.

In other words, according to a semiconductor device manufacturing method according to the present invention, the SiO₂ film 104 is subjected to the wet process while the interior of the trench 106 is in a hydrophilized state. Accordingly, the wet process solution 107 is not repelled by the trench 106, and formation of an air bubble at the time of removal of the SiO₂ film 104 is suppressed. This makes it possible to suppress generation of a residue of the SiO₂ film 104. The occurrence of defects due to such a residue is reduced, and the yields and reliability of semiconductor devices can be improved.

A semiconductor device manufacturing method according to the present invention is not limited to the above-described embodiment, and various modifications may be made.

What is claimed is:

1. A semiconductor device manufacturing method comprising:
forming a mask layer on a silicon substrate;
forming a photo resist layer on the mask layer;
forming a pattern surrounding a predetermined region in the photo resist layer;
etching the mask layer using the pattern to form a mask;
forming a trench in the silicon substrate using the mask;
cleaning an interior of the trench with a cleaning solution containing hydrofluoric acid;
performing hydrophilic treatment on the interior of the trench; and
removing the mask by a wet process after the hydrophilic treatment step.

2. The semiconductor device manufacturing method according to claim 1, wherein the mask layer includes a silicon oxide film.

3. The semiconductor device manufacturing method according to claim 1, wherein the mask layer includes a silicon oxide film and a silicon nitride film.

4. The semiconductor device manufacturing method according to claim 1, wherein the wet process is performed using a solution containing hydrofluoric acid-ammonium fluoride mixture.

5. The semiconductor device manufacturing method according to claim 1, wherein the hydrophilic treatment is performed using APM and SPM.

6. The semiconductor device manufacturing method according to claim 1, wherein the hydrophilic treatment is performed by oxidation.

7. The semiconductor device manufacturing method according to claim 1, wherein formation of the trench is performed by dry etching.

8. The semiconductor device manufacturing method according to claim 1, wherein the photo resist layer is removed after etching the mask layer using the pattern and before forming the trench in the silicon substrate.
